(19) United States
(12) Patent Application Publication
(10) Pub. No.: US 2025/0067601 A1
(43) Pub. Date: Feb. 27, 2025

(54) BOLOMETER AND MANUFACTURING METHOD

(71) Applicant: NEC Corporation, Tokyo (JP)

(72) Inventor: Mayumi KOSAKA, Tokyo (JP)

(73) Assignee: NEC Corporation, Tokyo (JP)

(21) Appl. No.: 18/791,534

(22) Filed: Aug. 1, 2024

(30) Foreign Application Priority Data
Aug. 23, 2023 (JP) 2023-135769

(51) Int. Cl. G01J 5/20; H10N 15/10

(52) U.S. Cl. CPC G01J 5/20; H10N 15/15

(57) ABSTRACT

A bolometer includes a base material that has a stacking surface, two electrodes each of which has a main surface and a side surface extending from the main surface to the stacking surface, and a film that contains carbon nanotubes, in which the film includes a first portion that is stacked on the main surface, a second portion that is stacked on the stacking surface between the two electrodes, and a connection portion that connects the first portion and the second portion and provided on the side surface, and in which an average film thickness of the second portion is less than 10 nm.

### CROSS-REFERENCE TO RELATED APPLICATION

Priority is claimed on Japanese Patent Application No. 2023-135769, filed Aug. 23, 2023, the content of which is incorporated herein by reference.

### BACKGROUND ART

The present disclosure relates to a bolometer and a manufacturing method.

It is known that a bolometer is used as an infrared sensor.

For example, Japanese Unexamined Patent Application, First Publication No. 2022-25051 (hereinafter referred to as Patent Document 1) discloses a bolometer including a film made of carbon nanotubes.

### SUMMARY

In the bolometer disclosed in Patent Document 1 the film made of carbon nanotubes is formed by using a printing technique, and in this case, it may be difficult to reduce the resistance of the bolometer.

An example object of the present disclosure is to provide a bolometer and a manufacturing method for solving the above-described problem.

A bolometer of the present disclosure includes a base material that has a stacking surface, two electrodes each of which has a main surface and a side surface extending from the main surface to the stacking surface, and a film that contains carbon nanotubes, in which the film includes a first portion that is stacked on the main surface, a second portion that is stacked on the stacking surface between the two electrodes, and a connection portion that connects the first portion and the second portion and provided on the side surface, and in which an average film thickness of the second portion is less than 10 nm.

A manufacturing method of the present disclosure includes preparing a base material that has a stacking surface, and two electrodes each of which includes a main surface and a side surface extending from the main surface to the stacking surface, immersing the base material in a dispersion liquid containing carbon nanotubes, and pulling up the immersed base material at a moving speed of 0.3 μm/s or less such that the stacking surface passes through a liquid surface of the dispersion liquid, in which the dispersion liquid contains carbon nanotubes having a concentration of 0.0001% to 0.005%, and a surfactant having a concentration of 0.05% to 0.08%.

According to a bolometer and a manufacturing method according to the present disclosure, it is easy to achieve a reduction in resistance.

### BRIEF DESCRIPTION OF THE DRAWINGS

FIG. 1 is a cross-sectional view I showing an example of a configuration of a bolometer according to the present disclosure.

FIG. 2 is a flowchart I showing an example of processes in a manufacturing method according to the present disclosure.

FIG. 3 is an explanatory diagram I of dip coating in one process in the manufacturing method according to the present disclosure.

FIG. 4 is an explanatory diagram II of dip coating in one process in the manufacturing method according to the present disclosure.

FIG. 5 is a cross-sectional view of an element in which an electrode is formed on a CNT film in Comparative Example 1.

FIG. 6 is a cross-sectional view of an element in which a CNT film is formed by a casting method after forming an electrode in Comparative Example 2.

FIG. 7 is a SEM image captured in the direction of an arrow B in FIG. 6.

FIG. 8 is a cross-sectional view II showing an example of a configuration of a bolometer according to the present disclosure.

FIG. 9 is a flowchart II showing an example of processes in the manufacturing method according to the present disclosure.

FIG. 10 is a cross-sectional view showing an example of a configuration of a bolometer according to the present disclosure.

FIG. 11 is a flowchart showing an example of processes in the manufacturing method according to the present disclosure.

FIG. 12 is a SEM image i of a film of a bolometer in an example.

FIG. 13 is a SEM image ii of a film of a bolometer in an example.

FIG. 14 is an enlarged view of a part C in FIG. 13.

FIG. 15 is a cross-sectional TEM image of a film of a bolometer in an example.

FIG. 16 is a comparison table showing an average film thickness of each film in an example, and a resistance value and a TCR value at 3 V.

### EXAMPLE EMBODIMENT

Each example embodiment of the present disclosure will be described below with reference to the drawings. The interpretation of the scope of the present disclosure should be limited to the drawings and specific configurations used in each example embodiment. The same or equivalent components in all of the drawings are denoted by the same reference numerals, and repeated description will be omitted.

In the present disclosure, the drawings are associated with one or more example embodiments.

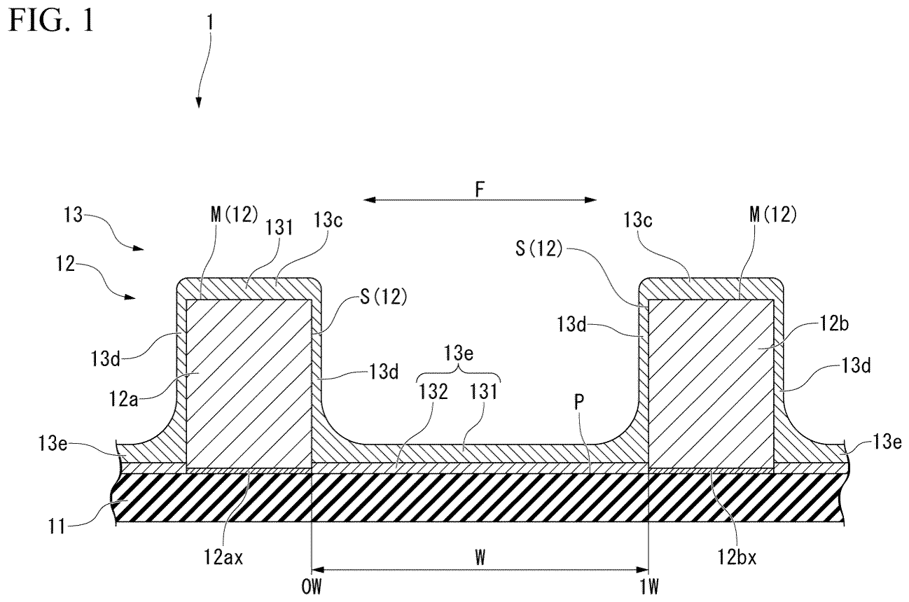

In the present disclosure, an example of a configuration of a bolometer will be described below with reference to FIGS. 1 to 4.

### (Configuration of Bolometer)

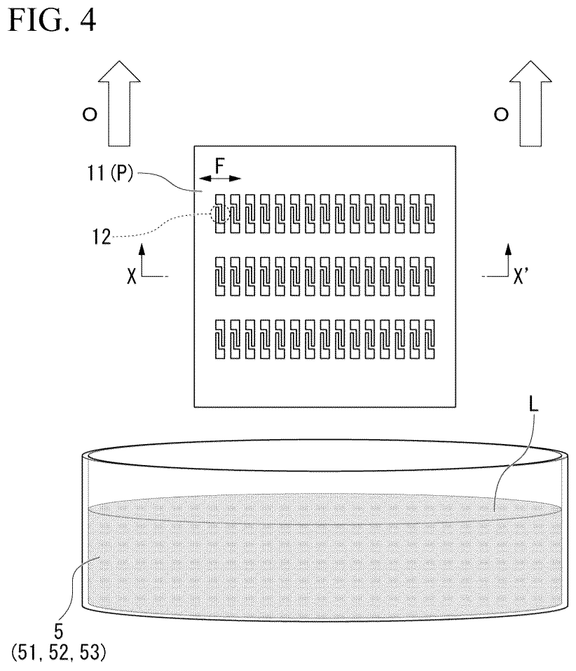

For example, the cross-sectional view of the bolometer in the present disclosure is a cross-sectional view taken along the cutting line X-X′ in FIG. 4.

A bolometer 1 is used in a sensor for detecting infrared rays.

As shown in FIG. 1, the bolometer 1 includes a base material 11, an electrode 12, and a film 13.

The base material 11 has a stacking surface P.

The base material 11 includes, for example, a Si substrate processed using a silicon wafer.

The base material 11 may include, for example, a monomer such as Parylene (registered trademark), a resin such as polyimide, or an organic material such as plastic.

A read circuit, for example, may be formed on the base material 11.

The base material 11 may have, for example, an electrically insulating base insulating layer. Methods of forming the base insulating layer include performing heat treatment on the base material 11 or directly forming the base insulating layer by a chemical vapor deposition (CVD). The base insulating layer is made of, for example, silicon oxide, silicon nitride, or the like.

### (Electrode 12)

The electrode 12 has two electrodes (a first electrode 12a and a second electrode 12b) each of which has a main surface M and a side surface S extending from the main surface M to the stacking surface P.

The electrode 12 is an electrode using, for example, Au, Al, Ti, or an alloy mainly containing these.

As an example, the first electrode 12a includes a base layer (12ax) for an electrode. Similarly, the second electrode 12b includes a base layer (12bx) for an electrode. The base layers (12ax, 12bx) may be layers containing Ti.

The thickness of the electrode 12 can be adjusted as appropriate. The thickness of the electrode 12 is, for example, 10 nm to 1.0 mm. The thickness of the electrode 12 is, for example, 50 nm to 1.0 μm.

The distance between the two electrodes (the first electrode 12a and the second electrode 12b) can be adjusted as appropriate. The distance between the two electrodes (the first electrode 12a and the second electrode 12b) is, for example, 1.0 μm to 500 μm. The distance between the two electrodes (the first electrode 12a and the second electrode 12b) is, for example, 5.0 μm to 200 μm.

### (Film)

The film 13 includes carbon nano tubes (CNTs) 51. The film 13 including the CNTs 51 may function, for example, as an infrared light receiving part.

The film 13 has a first portion 13c that is stacked on a main surface M of the electrode 12, a second portion 13e that is stacked on the stacking surface P between the two electrodes (the first electrode 12a and the second electrode 12b), and a connection portion 13d that connects the first portion 13c and the second portion 13e on a side surface S. Thereby, CNTs that are stacked on the main surface M of the electrode 12 and CNTs that are stacked on the stacking surface P between the two electrodes are electrically connected to each other by CNTs formed in the connection portion 13d.

The second portion 13e of the film 13 may include, for example, a first orientation layer 131 in which CNTs 51 are oriented (carbon nanotubes). Thereby, a plurality of oriented CNTs connect the two electrodes (the first electrode 12a and the second electrode 12b), and thus the CNTs 51 in the film 13 are electrically connected with an increased number of conductive paths. Thereby, the resistance value of the entire film 13 is decreased, making it easy to reduce the resistance of the bolometer 1.

The first orientation layer 131 may be, for example, an orientation layer in which wall surfaces of the CNTs are bonded together and aligned in the same direction.

The first orientation layer 131 may be, for example, an orientation layer in which several to several tens of CNTs are bundled together in the same direction by bonding parts of the wall surfaces of the CNTs together, and these CNT bundles are aligned in the same direction.

The first orientation layer 131 may be, for example, an orientation layer in which CNT bundles are aligned in the same direction at an interval equal to or greater than the diameter of at least one CNT.

The first orientation layer 131 may be, for example, an orientation film that includes CNTs or CNT bundles aligned in a CNT orientation direction and angle different from the orientation direction and angle in which the above-described CNTs or CNT bundles aligned in the same direction are aligned for connecting the above-described CNTs or CNT bundles aligned in the same direction.

The second portion 13e of the film 13 may include, for example, a base layer 132 between the stacking surface P and the first orientation layer 131.

The base layer 132 may be, for example, a second orientation layer in which the CNTs 51 are oriented (carbon nanotubes). In this case, the second orientation layer may be an orientation layer having the characteristics of the first orientation layer described above.

In the base layer 132 (second orientation layer), the density of CNTs may be, for example, higher than the density of CNTs in the first orientation layer 131.

The base layer 132 may be, for example, a non-orientation layer in which the CNTs are directed to random directions to form a network.

The base layer 132 may be, for example, a non-orientation layer in which CNTs form locally oriented domains, and these locally oriented domains are directed to random directions to form a network.

The average film thickness of the second portion 13e is, for example, equal to or greater than 1.0 nm and less than 10 nm. The total average film thickness of the first orientation layer 131 and the base layer 132 of the second portion 13e is, for example, equal to or greater than 1.0 nm and less than 10 nm.

The average film thickness of the first orientation layer 131 of the second portion 13e is, for example, equal to or less than 9.0 nm. The average film thickness of the first orientation layer 131 of the second portion 13e is, for example, equal to or greater than 0.5 nm and equal to or less than 5.0 nm.

The film thickness of the second portion 13e of the film 13 can be set to a film thickness of the second portion 13e in a region of 60% of the center of the second portion 13e. In FIG. 1, in a case where the distance between the electrodes is w, the film thickness of the second portion 13e is set to, for example, a film thickness of the second portion 13e in a region in the range of 0.6 w from the center line of the distance w, specifically, in the range of 0.2 w to 0.8 w in a case where a left end of a region between the electrodes is set to 0 w and a right end is set to 1 w. The film thickness of the second portion 13e may be measured directly using a microscope, or obtained from an image captured and observed using a microscope, as will be described below.

### (CNT)

The CNT 51 is a fibrous material of which the diameter is 0.6 nm to 1.5 nm and the length of a single CNT is 100 nm to 5.0 um. The properties of the CNT 51 change depending on the arrangement of six-membered rings in the circumferential direction.

Regarding the CNT 51, a cylindrical CNT made from a single graphene sheet is referred to as a single-layer CNT, and a plurality of CNTs with different diameters coaxially overlapping each other and formed as a plurality of layers are referred to as a multi-layer CNT. CNTs formed as a double layer are referred to as a double-layer CNT.

The CNT 51 may be, for example, any of a single-layer CNT, a double-layer CNT, or a multi-layer CNT.

As an example, the CNT 51 of the present disclosure is a single-layer CNT.

There are two types of CNT 51: a semiconducting type that exhibits semiconducting properties, and a metallic type that exhibits metallic properties. Single-layer CNTs usually contain semiconducting CNTs and metallic CNTs in a 2:1 ratio. For this reason, in a case where a large amount of CNTs that exhibit one type of property are used, a separation process is necessary.

The CNT 51 of the present disclosure contains a mixture of semiconductor CNTs and metallic CNTs. The CNT 51 may be obtained, for example, by performing a process of separating semiconducting CNTs from a single-layer CNT, and may contain 90% or more semiconducting CNTs. The CNT 51 may contain, for example, 92% or more semiconducting CNTs. The CNT 51 may contain, for example, 94% or more semiconducting CNTs. The CNT 51 may contain, for example, 96% or more semiconducting CNTs. The CNT 51 may contain, for example, 98% or more semiconducting CNTs.

### (Manufacturing Method)

A manufacturing method in the present disclosure will be described.

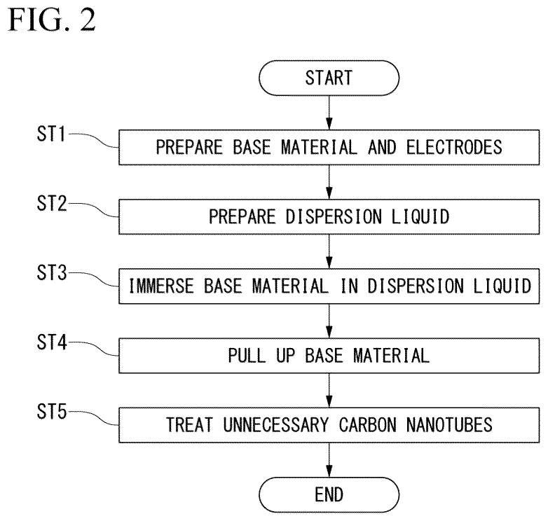

The manufacturing method in the present disclosure is performed in accordance with a flow shown in FIG. 2.

First, an operator prepares the base material 11 and two electrodes (the first electrode 12a and the second electrode 12b) (ST1).

Specifically, the electrode 12 is formed on the stacking surface P of the base material 11 by deposition, sputtering, or the like.

In the present disclosure, the electrode 12 is formed by deposition.

The operator may form, for example, a resist film on the stacking surface P in advance in ST1 to remove unnecessary parts included in the film 13 by lift-off in ST5 to be described below.

Next, the operator prepares a dispersion liquid 5 (ST2).

Specifically, the operator prepares the dispersion liquid 5 by mixing the CNT 51, a surfactant 52, and a dispersion medium 53. Ultrasonic treatment, for example, is used for the mixing of the dispersion liquid 5.

The operator can disperse the CNTs 51 sufficiently by using the surfactant 52 for the dispersion liquid 5. In addition, the surfactant 52 may be a non-ionic surfactant. Non-ionic surfactants are easier to remove by washing, heat treatment, and the like than ionic surfactants.

Examples of the non-ionic surfactant include a polyoxyethylene alkyl ether solution such as polyoxyethylene (100) stearyl ether or polyoxyethylene (23) lauryl ether.

The dispersion medium 53 is not particularly limited if it is a solvent that can disperse and suspend the CNTs 51 in the dispersion liquid 5, and for example, water, heavy water, an organic solvent, an ionic liquid, or a mixture of thereof can be used.

The operator can sufficiently disperse the aggregated metallic CNTs and semiconducting CNTs by performing ultrasonic treatment on the mixture of the dispersion liquid 5. In addition, the operator can appropriately control the length of the CNT 51 by controlling the output of ultrasonic waves and a treatment time in the ultrasonic treatment.

For example, a dispersion liquid in which the surfactant 52, the metallic CNTs, and the semiconducting CNTs are uniformly dispersed in the dispersion medium 53 may be used as the dispersion liquid 5. For example, the semiconducting CNTs may be separated or concentrated for use to obtain a high TCR in the bolometer.

Carbon nanotubes can be separated by, for example, an electric-field-induced layer formation method (ELF method: see, for example, K. Ihara et al. J. Phys. Chem. C. 2011, 115, 22827-22832, and Japanese Patent No. 5717233, which are incorporated herein by reference).

An example of a separation method using the ELF method will be described below. Separation is performed by carrier-free electrophoresis by introducing a CNT dispersion liquid A in which metallic CNTs and semiconducting CNTs are dispersed using a non-ionic surfactant into a vertical separation device with a double-tube structure and applying a voltage to electrodes disposed above and below. In this method, the semiconducting CNTs move to an anode side, and the metallic CNTs move to a cathode side.

A dispersion liquid of semiconducting CNTs obtained by a separation process step generally contains semiconducting CNTs at a proportion of 67% by mass or more, preferably 70% by mass or more, more preferably 80% by mass or more, particularly preferably 90% by mass or more, more preferably 95% by mass or more, and still more preferably 99% by mass or more (an upper limit may be 100% by mass) in a total amount of CNTs contained in the dispersion liquid. A separation ratio of metallic and semiconducting CNTs can be analyzed by microscopic Raman spectroscopy and ultraviolet-visible-near infrared absorptiometry.

Part of the surfactant 52 is removed from the dispersion liquid 5 containing the semiconducting CNTs (representing the dispersion liquid of the semiconducting CNTs that have moved to the anode side) to prepare the dispersion liquid 5 in which the concentration of the surfactant 52 and the concentration of the CNTs 51 are adjusted.

The concentration of the CNTs 51 and the concentration of the surfactant 52 contained in the dispersion liquid 5 can be estimated from measurement performed using ultraviolet-visible-near infrared absorptiometry.

In ST2, the prepared dispersion liquid 5 contains the CNTs 51 having a concentration in the range of 0.0001% (by mass) to 0.005% (by mass) and the surfactant 52 having a concentration in the range of 0.05% to 0.08%. The prepared dispersion liquid 5 contains, for example, the CNTs 51 having a concentration in the range of 0.0002% (by mass) to 0.0005% (by mass) and the surfactant 52 having a concentration in the range of 0.05% (by mass) to 0.08% (by mass).

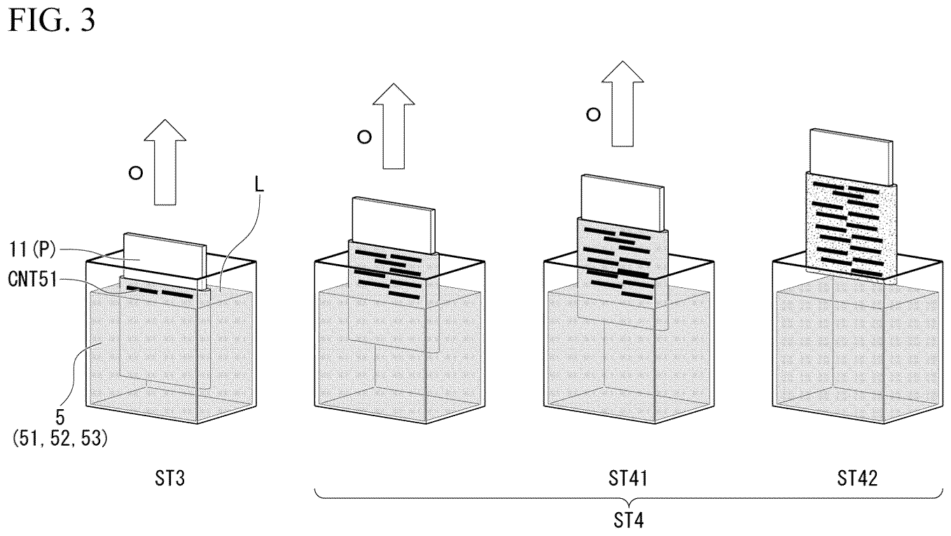

Next, as shown in FIG. 3, the operator immerses the base material 11 in the dispersion liquid 5 containing the CNTs 51 (ST3).

Then, the operator pulls up the immersed base material 11 so that the stacking surface P passes through a liquid surface of the dispersion liquid 5 (ST4).

A dip coater, for example, may be used to pull up the base material 11 at a constant speed.

In a case where the operator pulls up the base material 11, an angle θ (−90°≤θ≤90°) between an interface L and the base material 11 is not particularly limited. The angle θ between the interface L and the base material 11 is, for example, −30°≤θ≤30°. The angle θ between the interface L and the base material 11 is, for example, −20°≤θ≤20°. The angle θ between the interface L and the base material 11 is, for example, −10°≤θ≤100.

A moving speed in a case where the immersed base material 11 is pulled up is, for example, equal to or less than 0.3 μm/s. A moving speed in a case where the immersed base material 11 is pulled up is, for example, equal to or less than 0.1 μm/s.

The operator can control the orientation of the first orientation layer 131 by appropriately changing the moving speed at the time of pulling up the immersed base material 11.

The operator sets the moving speed at the time of pulling up the immersed base material 11, for example, to equal to or less than 0.3 μm/s, and thus the CNTs 51 move onto the stacking surface P of the base material 11 in a state where they are oriented in parallel with the interface of the dispersion liquid 5.

The operator sets the moving speed at the time of pulling up the immersed base material 11, for example, to equal to or less than 0.1 μm/s, thereby making it easier for the CNTs 51 to be oriented in the first orientation layer 131 included in the film 13 of the manufactured bolometer 1. In the manufactured bolometer 1, two electrodes (the first electrode 12a and the second electrode 12b) are connected by a plurality of more oriented CNTs, and thus the film 13 is electrically connected with an increased number of conductive paths. Thereby, the entire resistance value of the film 13 is decreased, making it easy to reduce the resistance of the bolometer 1.

As shown in FIGS. 1 and 4, the operator pulls up the base material 11, for example, along the stacking surface P thereof in a direction O intersecting an opposing direction F of the side surfaces S of the two electrodes (the first electrode 12a and the second electrode 12b).

The first orientation layer 131 in which the CNTs 51 are oriented is formed by gradually pulling up the immersed base material 11 from the interface L of the dispersion liquid 5 (ST41), and then gradually drying the dispersion liquid 5 attached to the stacking surface P (ST42).

In addition, immediately after the stacking surface P passes through the interface L of the dispersion liquid 5, a second orientation layer in which the CNTs 51 are oriented is formed in the base layer 132.

In this case, the film 13 including the first orientation layer 131 and the base layer 132 (second orientation layer) located between the stacking surface P and the first orientation layer 131 is formed on the stacking surface P.

The base layer 132 (second orientation layer) formed in ST4 may be, for example, an orientation layer having the following characteristics.

The base layer 132 (second orientation layer) may be, for example, an orientation layer in which the density of CNTs may be higher than the density of CNTs in the first orientation layer 131.

The base layer 132 (second orientation layer) may be, for example, an orientation layer in which the wall surfaces of the CNTs are bonded together and aligned in the same direction.

The base layer 132 (second orientation layer) may be, for example, an orientation layer in which several to several tens of CNTs are bundled together in the same direction by bonding parts of the wall surfaces of the CNTs together, and these CNT bundles are aligned in the same direction.

The base layer 132 (second orientation layer) may be, for example, an orientation layer in which CNT bundles are aligned in the same direction at an interval equal to or greater than the diameter of at least one CNT.

The base layer 132 (second orientation layer) may be, for example, an orientation layer that includes CNTs or CNT bundles aligned in a CNT orientation direction and angle different from the orientation direction and angle in which the above-described CNTs or CNT bundles aligned in the same direction are aligned for connecting the above-described CNTs or CNT bundles aligned in the same direction.

As described above, the film 13 including the first orientation layer 131 is formed in the second portion 13e.

The film 13 formed on the stacking surface P includes the first portion 13c, the second portion 13e, and the connection portion 13d that connects the first portion 13c and the second portion 13e. Thereby, CNTs stacked on the main surface M of the electrode 12 and CNTs stacked on the stacking surface P between the two electrodes (the first electrode 12a and the second electrode 12b) are electrically connected by the CNTs formed in the connection portion 13d. That is, it is possible to make it easy to form a conductive path for the CNTs 51 to thereby reduce the resistance of the bolometer 1.

The first orientation layer 131 may be formed, for example, over the first portion 13c, the second portion 13e, and the connection portion 13d connecting the first portion 13c and the second portion 13e. Thereby, the CNTs stacked on the main surface M of the electrode 12 and the CNTs stacked on the stacking surface P between the two electrodes (the first electrode 12a and the second electrode 12b) are electrically connected by the CNTs formed in the connection portion 13d. That is, the manufacturing method in the present disclosure makes it easy to form a conductive path for the CNTs and makes it possible to reduce the resistance of the bolometer 1. In this case, the base layer 132 (second orientation layer) may be formed mainly in the second portion 13e. For example, the base layer 132 (second orientation layer) formed in the second portion 13e may be configured not to be connected to the first portion 13c. For example, the base layer 132 (second orientation layer) may be configured not to be formed in the first portion 13c or the connection portion 13d connected to the first portion 13c.

Next, the operator treats unnecessary carbon nanotubes from the film 13 formed on the base material 11 in a case where it is pulled up, as necessary (ST5).

For example, it is conceivable that the operator forms a resist film on the stacking surface P in advance in ST1. In this case, the operator removes unnecessary parts included in the film 13 by lift-off by using a protective film.

In order to remove unnecessary parts included in the film 13 by etching, the operator may form, for example, a protective film or an infrared absorbing structure directly on the film 13. In this case, the operator removes the unnecessary parts included in the film 13 by etching, oxygen plasma treatment, or the like by using the protective film.

Examples of the protective film include a resist film and an acrylic resin such as polymethyl methacrylate resin (PMMA).

Here, the film 13 electrically connecting the electrodes 12 is formed on the stacking surface P of the base material 11 (completion).

### (Film Thickness Measurement)

Furthermore, the film thickness in the second portion 13e of the manufactured bolometer is measured as an average film thickness.

The film thickness of the second portion 13e of the film 13 can be set to be a film thickness of the second portion 13e in a region of 60% of the center of the second portion 13e. In FIG. 1, in a case where a distance between the electrodes is w, the film thickness of the second portion 13e is set to, for example, a film thickness of the second portion 13e in a region in the range of 0.6 w from the center line of the distance w, specifically, in the range of 0.2 w to 0.8 w in a case where a left end of a region between the electrodes is set to 0 w and a right end is set to 1 w.

In this case, the operator may directly measure the film thickness by using an atomic force microscope (AFM), a scanning electron microscope (SEM), a transmission electron microscope (TEM), or the like, or measure the film thickness from an observed image captured using any of these microscopes.

### (Actions and Effects)

According to the bolometer of the present disclosure, the CNTs stacked on the main surface M of the electrode 12 and the CNTs stacked on the stacking surface P between the two electrodes (the first electrode 12a and the second electrode 12b) are electrically connected to each other by the CNTs formed in the connection portion 13d. Thereby, it is possible to make it easy to form a conductive path for the CNTs 51 to thereby reduce the resistance of the bolometer 1. In addition, as shown by the first orientation layer 131, the electrically connected CNTs 51 are oriented, and thus it is possible to achieve a further reduction in resistance.

Thus, it is easy to reduce the resistance of the bolometer of the present disclosure.

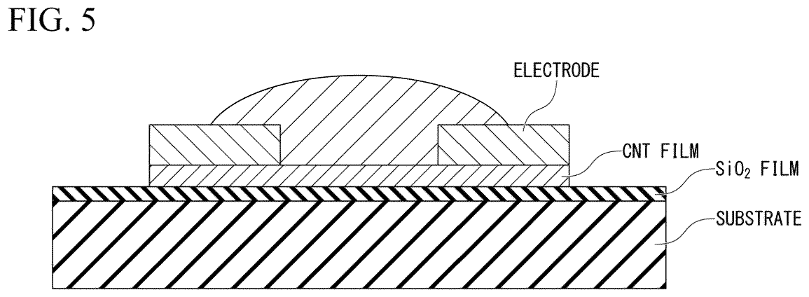

FIGS. 5 to 7 show bolometers according to Comparative Example 1 and Comparative Example 2.

As disclosed in FIG. 5, in “a bolometer in which an electrode is formed on a CNT film containing CNTs 51” in Comparative Example 1, a lower side of the electrode and the CNT film are electrically connected to each other.

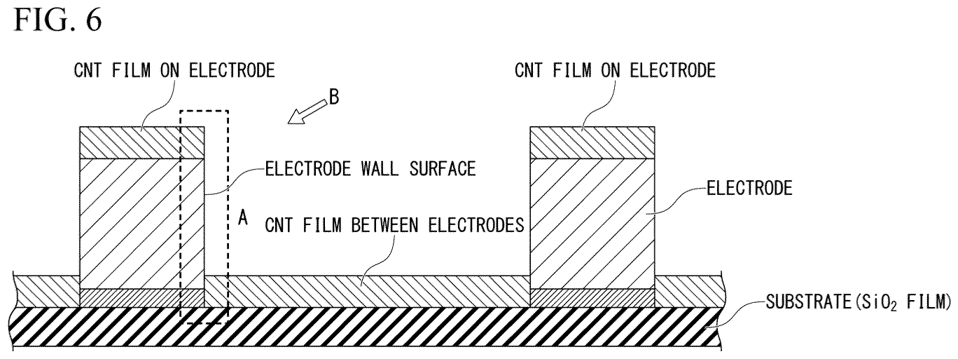

However, as disclosed in FIG. 6, in “a bolometer in which an electrode is formed first and then a film containing CNTs (a CNT film on an electrode, a CNT film between electrodes) is formed by a casting method” in Comparative Example 2, it may be difficult to electrically connect the CNT film on the electrode and the CNT film between the electrodes.

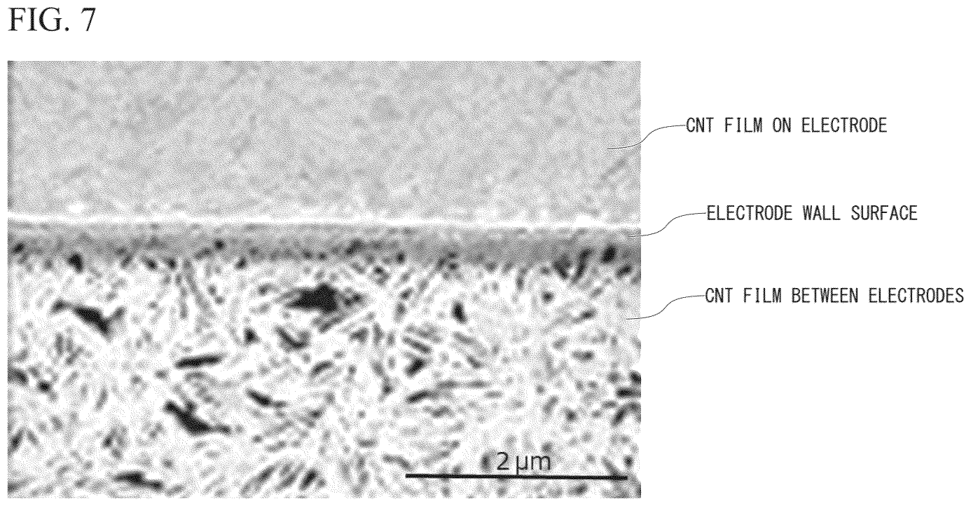

FIG. 7, which is a diagram in a case where a region A in FIG. 6 is viewed from the direction of an arrow B, shows that CNTs may be hardly attached to an electrode wall surface, and the CNT film on the electrode and the CNT film between the electrodes are not electrically connected to each other.

A light receiving portion of a bolometer of a CNT non-cooling infrared sensor has a structure in which a CNT film formed between electrodes is electrically connected to the electrodes. For this reason, how CNTs are bonded to the electrodes affects a resistance value.

However, in a case where the CNT film between the electrodes is thickened to make it easy to form a conductive path for the CNTs 51 and achieve a reduction in resistance, the content of metallic CNTs included in the CNT film between the electrodes increases, causing a problem of a decrease in an absolute value of a temperature coefficient of resistance (TCR).

Thus, in order to decrease a resistance value of the bolometer without decreasing the absolute value of the TCR, it is necessary to allow the CNT film between the electrodes and the CNT film on the electrodes electrically connected to each other.

In contrast to the comparative example, in the bolometer 1 of the present disclosure, the film 13 is electrically connected to the CNTs stacked on the main surface M of the electrode 12 and the CNTs stacked on the stacking surface P between the two electrodes (the first electrode 12a and the second electrode 12b) by the CNTs formed in the connection portion 13d. Thereby, it is possible to make it easy to form a conductive path for the CNTs 51 to thereby reduce the resistance of the bolometer 1. In addition, the CNTs 51 in the first orientation layer 131 are oriented, and thus the resistance of the film 13 including the CNTs 51 can be further reduced. For this reason, it is easy to reduce the resistance of the bolometer 1 of the present disclosure.

In addition, the bolometer 1 of the present disclosure does not need to be thickened to achieve a reduction in resistance. For this reason, the content of the metallic CNTs in the film 13 is not increased, and it is possible to achieve a reduction in resistance without decreasing the absolute value of the TCR.

Further, the bolometer of the present disclosure includes a base material having a stacking surface, two electrodes each having a main surface and a side surface extending from the main surface to the stacking surface, and a film containing carbon nanotubes, the film having a first portion stacked on the main surface, a second portion stacked on the stacking surface between the two electrodes, and a connection portion connecting the first portion and the second portion on the side surface to thereby obtain the following effects.

In the bolometer of the present disclosure, the CNTs stacked on the main surface M of the electrode 12 and the CNTs stacked on the stacking surface P between the two electrodes (the first electrode 12a and the second electrode 12b) are electrically connected by the CNTs formed in the connection portion 13d. Thereby, it is possible to obtain an effect that the bolometer 1 of the present disclosure can make it easy to form a conductive path for the CNTs 51 to thereby achieve a reduction in resistance. For this reason, it is easy to reduce the resistance of the bolometer of the present disclosure.

Further, in the bolometer of the present disclosure, an average film thickness of the second portion 13e is less than 10 nm, and thus it is also possible to obtain an effect that in a case where the CNT 51 in which semiconducting and metallic CNTs are mixed is used, the metallic CNTs can only exist within a range in which the average film thickness of the second portion 13e is less than 10 nm, and thus a decrease in an absolute value of a TCR can be suppressed.

Additionally, in the bolometer of the present disclosure, the second portion includes a first orientation layer in which the carbon nanotubes are oriented, and thus it is also possible to further obtain an effect that the film 13 is electrically connected with an increased number of conductive paths by connecting two electrodes (the first electrode 12a and the second electrode 12b) with a plurality of oriented CNTs. Thereby, the entire resistance value of the film 13 is decreased, making it easy to reduce the resistance of the bolometer 1.

The CNT 51 disclosed above is a mixture of semiconducting and metallic CNTs, but separated semiconducting CNTs may also be used. Thereby, an absolute value of a TCR of the bolometer 1 can be increased.

The first orientation layer 131 described above may be provided over the first portion 13c, the connection portion 13d, and the second portion 13e. Thereby, the CNTs stacked on the main surface M of the electrode 12 and the CNTs stacked on the stacking surface P between the two electrodes (the first electrode 12a and the second electrode 12b) are electrically connected by the CNTs formed in the connection portion 13d. In this case, the number of conductive paths for the CNTs 51 is increased, thereby making it possible to reduce the resistance of the bolometer 1.

The second portion 13e described above may include a plurality of first orientation layers 131. By arranging a number of first orientation layers in which a plurality of CNTs are oriented in the stacking direction of the stacking surface P, it is easy to form a conductive path to the electrode 12, and it can be expected that the resistance of the bolometer 1 will be reduced.

In the above disclosure, the second portion 13e of the bolometer 1 includes the first orientation layer in which the CNTs 51 are oriented, and thus the film 13 is electrically connected by connecting the two electrodes (the first electrode 12a and the second electrode 12b) with the plurality of oriented CNTs. Thereby, it is disclosed that the entire resistance value of the film 13 is decreased, making it easy to reduce the resistance of the bolometer 1.

On the other hand, a bolometer in the following disclosure focuses on the fact that a base layer 1320 is uniformly formed in a second portion 13e, which makes it easy for a first orientation layer 131 to be formed as a uniform orientation layer.

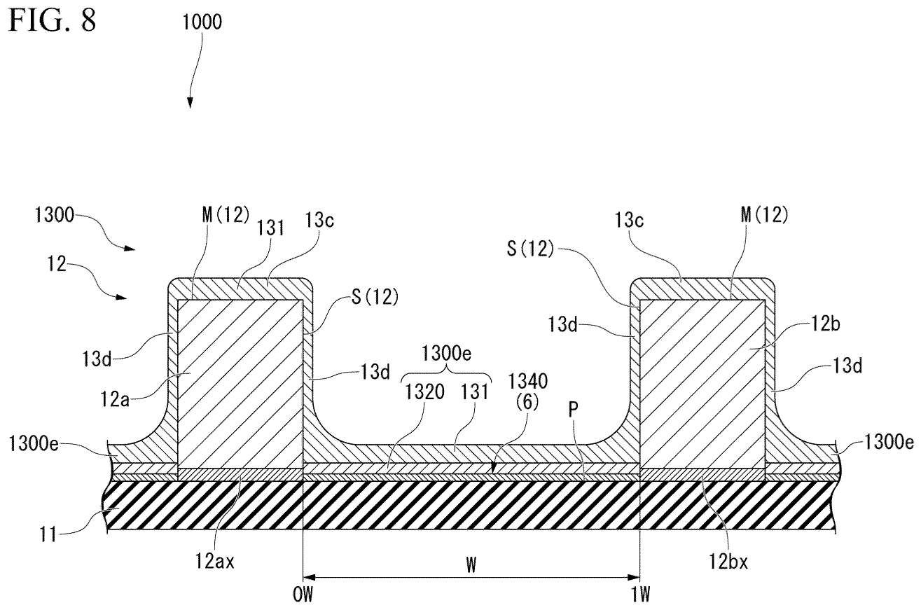

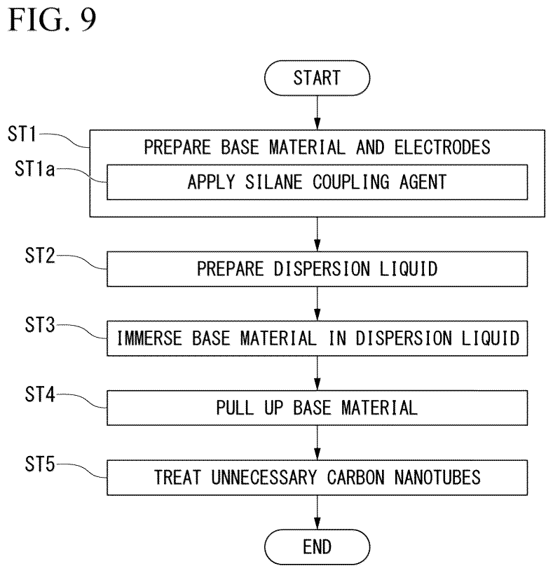

Hereinafter, an example of a configuration of a bolometer in the present disclosure will be described with reference to FIGS. 8 and 9.

Components in common with those described above are given the same reference numerals, and detailed description thereof will be omitted.

### (Configuration)

As shown in FIG. 8, a bolometer 1000 includes a base material 11, an electrode 12, and a film 13.

A film 1300 includes, for example, a first orientation layer 131 in which CNTs 51 are oriented, and a base layer 1320 in which the CNTs 51 are directed to random directions as compared to the first orientation layer 131.

The base layer 1320 may be, for example, a non-orientation layer in which CNTs are directed to random directions to form a network.

The base layer 1320 may be, for example, a non-orientation layer in which CNTs form locally oriented domains, and these locally oriented domains are directed to random directions to form a network.

A second portion 1300e of the film 1300 includes, for example, a first orientation layer 131.

The second portion 1300e of the film 1300 includes, for example, the base layer 1320 between a stacking surface P and the first orientation layer 131.

The film 1300 may include, for example, an adhesive layer 1340.

An average film thickness of the second portion 1300e is, for example, equal to or greater than 1.0 nm and less than 10 nm.

A total average film thickness of the first orientation layer 131 and the base layer 1320 included in the second portion 1300e of the film 1300 is, for example, equal to or greater than 1.0 nm and less than 10 nm.

An average film thickness of the first orientation layer 131 of the second portion 1300e is, for example, equal to or less than 9.0 nm. The average film thickness of the first orientation layer 131 of the second portion 1300e is, for example, equal to or greater than 0.5 nm and equal to or less than 5.0 nm.

The film thickness of the second portion 1300e of the film 13 is measured in a manner similar to the measurement of the film thickness of the second portion 13e in some of the example embodiments described above.

The second portion 1300e of the film 1300 may include, for example, the adhesive layer 1340. The adhesive layer 1340 is a thin film for improving the adhesion performance of the CNTs 51 to an insulating layer of the base material 11. The adhesive layer 1340 includes a silane coupling agent 6 for forming the base layer 1320 on the base material 11. Examples of the silane coupling agent 6 include 3-aminopropyltriethoxysilane (APTES), 3-aminopropyltrimethoxysilane, 3-aminopropylmethyltriethoxysilane, 3-aminopropylmethyltrimethoxysilane, and the like.

An operator may use, for example, the silane coupling agent 6 having an amino group to improve the adhesion of the CNTs 51.

The adhesive layer 1340 is formed, for example, on the stacking surface P of the base material 11, thereby the CNTs 51 adhere to the base material 11 in a case where the base material 11 is immersed in the dispersion liquid 5 in the immersion process of ST3 due to an effect of the silane coupling agent 6, and a uniform base layer 1320 with little unevenness is stacked. The second portion 1300e has the following advantage by including the base layer 1320 between the stacking surface P and the first orientation layer 131. Due to the presence of the uniform base layer 1320, the first orientation layer 131 is easily formed as a uniform orientation layer. That is, a space SP (cavity) where the CNTs 51 are sparsely formed by sporadical adhesion of the CNTs 51 is not likely to be formed in the first orientation layer 131. Thereby, the CNTs 51 in the film 1300 are likely to be electrically connected to each other, making it easy to reduce the resistance of the bolometer 1000.

### (Method)

A manufacturing method in the present disclosure will be described.

The manufacturing method in the present disclosure is performed in accordance with a flow shown in FIG. 9.

Components in common with those of the bolometer 1 are given the same reference numerals, and detailed description thereof will be omitted.

First, an operator prepares the base material 11 and two electrodes (the first electrode 12a and the second electrode 12b) (ST1).

In a case where ST1 is performed, the operator may apply a silane coupling agent 6 onto the stacking surface P of the base material 11 (ST1a). The operator applies the silane coupling agent 6 onto the stacking surface P to form an adhesive layer 1340. Thereby, in ST3 to be described below, the CNTs 51 adhere due to an effect of the silane coupling agent 6 contained in the adhesive layer 1340, thereby further forming the base layer 1320.

Examples of the silane coupling agent 6 include 3-aminopropyltriethoxysilane (APTES), 3-aminopropyltrimethoxysilane, 3-aminopropylmethyltriethoxysilane, 3-aminopropylmethyltrimethoxysilane, and the like.

An operator may use the silane coupling agent 6, for example, having an amino group to improve the adhesion of the CNTs 51.

In the subsequent steps of ST2 to ST5, the same processing as in FIG. 2 is performed.

However, as the operator performs ST1a, the following changes are seen in ST3 and ST4 as compared to the case in FIG. 2.

In ST3, in the case where the operator performs the process of ST1a, the base material 11 is immersed in the dispersion liquid 5, thereby the base layer 1320 is formed on the stacking surface P of the base material 11. In the base layer 1320, CNTs are directed to random directions as compared to those of the first orientation layer 131.

In ST4, in the case where the operator performs the process of ST1a, the first orientation layer 131 is formed on the base layer 1320 already formed in ST3 in the second portion 1300e while the CNTs 51 are gradually deposited during drying. In this case, the film 1300 including the first orientation layer 131 and the base layer 1320 located between the stacking surface P and the first orientation layer 131 is formed on the stacking surface P.

In the bolometer 1000 of the present disclosure, which is formed by performing ST1, the second portion 1300e includes the first orientation layer 131 and the base layer 1320.

### (Actions and Effects)

According to the bolometer 1000 of the present disclosure, the second portion 1300e includes the base layer 1320 between the stacking surface P and the first orientation layer 131. Since the base layer is a uniform layer with little unevenness, the first orientation layer 131 is likely to be formed as a uniform orientation layer. That is, a space (cavity) where the CNTs 51 are sparse is not likely to be formed in the first orientation layer 131. Thereby, the CNTs 51 in the film 1300 are likely to be electrically connected to each other.

Thus, it is easy to reduce the resistance of the bolometer of the present disclosure.

The bolometer 1000 of the present disclosure has an effect in addition to the effects of the bolometer 1. In the bolometer 1000 of the present disclosure, the second portion 1300e includes the uniform base layer 1320 between the stacking surface P and the first orientation layer 131, the base layer 1320 being formed such that carbon nanotubes directed to random directions as compared to those of the first orientation layer 131, and thus the first orientation layer 131 is likely to be formed as a uniform orientation layer. That is, the space SP (which will be described below) where the CNTs 51 are sparsely formed by sporadical adhesion of the CNTs 51 is not likely to be formed in the first orientation layer 131. Thereby, the CNTs 51 in the film 1300 are likely to be electrically connected to each other, making it easy to reduce the resistance of the bolometer.

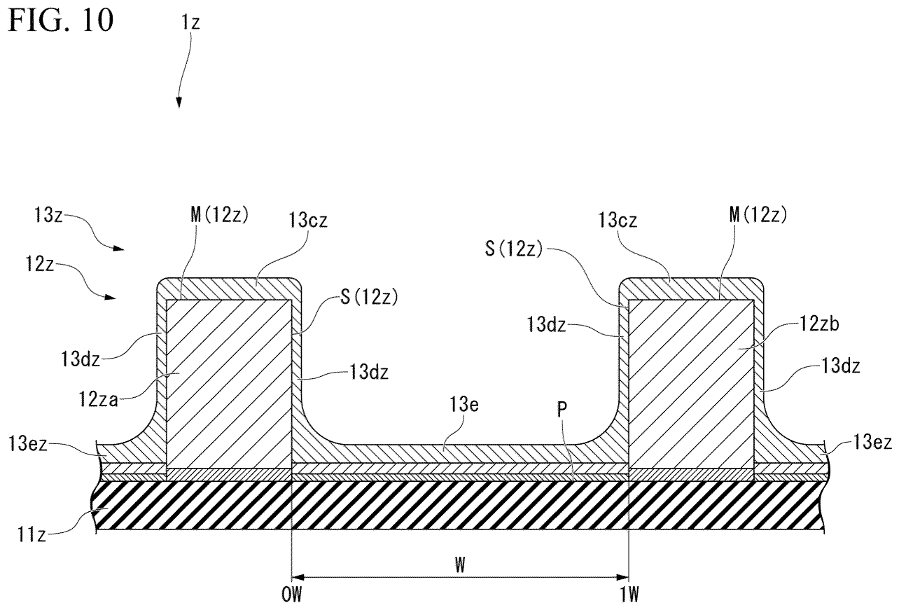

Hereinafter, an example of a configuration of a bolometer in the present disclosure will be described with reference to FIG. 10.

### (Configuration)

A bolometer 1z includes a base material 11z having a stacking surface P, two electrodes 12z (a first electrode 12za and a second electrode 12zb) each of which has a main surface M and a side surface S extending from the main surface M to the stacking surface P, and a film 13z containing carbon nanotubes. The film 13z has a first portion 13cz stacked on the main surface M, a second portion 13ez stacked on the stacking surface P between the two electrodes, and a connection portion 13dz connecting the first portion 13cz and the second portion 13ez on the side surface S, and an average film thickness of the second portion 13ez is less than 10 nm.

### (Actions and Effects)

According to the bolometer of the present disclosure, the CNTs stacked on the main surface M of the electrode 12z and the CNTs stacked on the stacking surface P between the two electrodes (the first electrode 12za and the second electrode 12zb) are electrically connected by the CNTs formed in the connection portion 13dz. Thereby, it is possible to make it easy to form a conductive path for the CNTs 51 to thereby reduce the resistance of the bolometer 1z.

Thus, it is easy to reduce the resistance of the bolometer of the present disclosure.

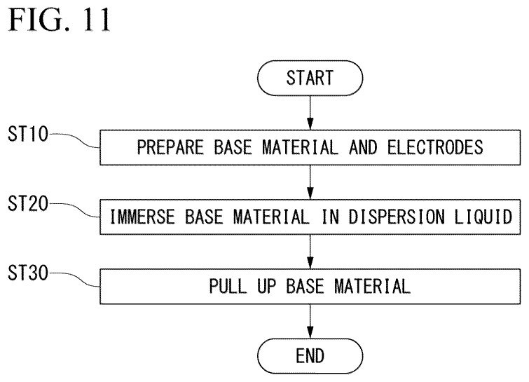

Hereinafter, an example of a manufacturing method in the present disclosure will be described with reference to FIG. 11.

The manufacturing method in the present disclosure is performed in accordance with a flow shown in FIG. 11.

The manufacturing method includes a step (ST10) of preparing a base material having a stacking surface and two electrodes each of which has a main surface and a side surface extending from the main surface to the stacking surface of the base material, a step (ST20) of immersing the base material in a dispersion liquid containing carbon nanotubes, and a step (ST30) of pulling up the immersed base material at a moving speed of 0.3 μm/s or less so that the stacking surface passes through a liquid surface of the dispersion liquid, the dispersion liquid containing carbon nanotubes at a concentration of 0.0001% to 0.005% and a surfactant at a concentration of 0.05% to 0.08%.

### (Actions and Effects)

According to the manufacturing method of the present disclosure, the CNTs stacked on the main surface of the electrode and the CNTs stacked on the stacking surface between the two electrodes are electrically connected by the CNTs formed in the connection portion. Thereby, it is possible to make it easy to form a conductive path for the CNTs 51 to thereby reduce the resistance of the bolometer.

Thus, according to the manufacturing method in the present disclosure, it is easy to achieve a reduction in resistance.

### Examples

Hereinafter, effects of the present disclosure will be described more specifically using examples. Conditions in the examples are examples of conditions adopted to confirm the feasibility and effects of the present disclosure, and the present disclosure is not limited to these examples of conditions. The present disclosure may adopt various conditions as long as the objectives of the present disclosure are achieved without departing from the gist of the present disclosure.

In this example, two types of bolometers were created.

On the other hand, in a bolometer (A), steps ST1 to ST5 in the flowchart of FIG. 2 were performed. For example, Example 1 was performed for the bolometer (A). In Example 1, the concentration of CNTs in a dispersion liquid 5 was 0.0005%, and the concentration of a surfactant was 0.05%.

On the other hand, in a bolometer (B), the process of ST1a was performed during ST1. That is, in the flowchart of FIG. 9, ST1 (ST1a) to ST5 were performed. In the bolometer (B), for example, Examples 2 to 6 were performed. In Example 2, the concentration of CNTs in a dispersion liquid was 0.0001%, and the concentration of a surfactant was 0.05%. Subsequently, in Example 3, the concentration of CNTs in a dispersion liquid was 0.0002%, and the concentration of a surfactant was 0.05%. Subsequently, in Example 4, the concentration of CNTs in a dispersion liquid was 0.0005%, and the concentration of a surfactant was 0.05%. Subsequently, in Example 5, the concentration of CNTs in a dispersion liquid was 0.005%, and the concentration of a surfactant was 0.05%. Subsequently, in Example 6, the concentration of CNTs in a dispersion liquid was 0.0005%, and the concentration of a surfactant was 0.08%.

The bolometers were created using the following method.

### (ST2) Preparation of Carbon Nanotube Dispersion Liquid

In ST2, the dispersion liquid 5 was prepared using the following method.

100 mg of single-layer CNT (Meijo Nanocarbon Co., Ltd., EC1.0 (diameter: approximately 1.1 nm to 1.5 nm, average diameter 1.2 nm) was placed in a quartz boat, and heat treatment was performed thereon in an electric furnace under a vacuum atmosphere. The heat treatment was performed at 900° C. for 2 hours. The weight after the heat treatment was reduced to 80 mg, indicating that surface functional groups and impurities had been removed. After the resulting single-layer CNT was crushed with tweezers, 12 mg thereof was immersed in 40 ml of a 1 wt % aqueous solution of a surfactant 52 (polyoxyethylene (100) stearylether) and sufficiently submerged, and then ultrasonic dispersion treatment (BRANSON ADVANCED-DIGITAL SONIFIER device, an output of 50 W) was performed four times for 30 minutes. Thereby, there were no CNT agglomerates in the solution. Furthermore, this CNT dispersion liquid was transferred to two ultracentrifuge tubes and ultracentrifuged. By this operation, bundles, a residual catalyst, and the like were removed, and a CNT dispersion liquid A was obtained. In order to observe the lengths and diameters of CNTs, this dispersion liquid was applied onto a SiO₂ substrate, dried at 100° C., and then observed using an atomic force microscope (AFM). As a result, it was found that 70% of single-layer CNTs were in a length range of 500 nm to 3 μm, and an average length was approximately 800 nm.

The CNT dispersion liquid A obtained as described above was introduced into a separation device with a double-tube structure. Approximately 15 ml of water, approximately 70 ml of the CNT dispersion liquid A, and approximately 10 ml of a 2 wt % aqueous solution of the surfactant 52 were put into an outer tube of a double tube, and approximately 20 ml of a 2 wt % aqueous solution of the surfactant 52 was put into an inner tube. Thereafter, a lower lid of the inner tube was opened, thereby creating a three-layer structure with different concentrations of the surfactant 52. The lower side of the inner tube was used as an anode and the upper side of the outer tube was used as a cathode, and a voltage of 200 V was applied, causing semiconducting CNTs to move to the anode side. On the other hand, metallic CNTs moved to the cathode side. The semiconducting CNTs and the metallic CNTs were completely separated approximately 80 hours after the start of separation. The separation process was performed at room temperature (approximately 25° C.). The dispersion liquid of the semiconducting CNTs that had moved to the anode side was recovered and analyzed by optical absorption spectroscopy, and it was found that the components of the metallic CNTs had been removed. Furthermore, 98 wt % of the dispersion liquid of the semiconducting CNTs that had moved to the anode side was semiconducting carbon nanotubes from Raman spectroscopy. The diameters of single-layer carbon nanotubes were mostly approximately 1.2 nm (70% or more), and an average diameter thereof was 1.2 nm.

Part of the surfactant 52 was removed from the dispersion liquid 5 containing 98 wt % of the semiconducting CNTs (showing the dispersion liquid of the semiconducting CNTs that had moved to the anode side), thereby creating a dispersion liquid 5 in which the concentration of the surfactant 52 and the concentration of the CNTs 51 were adjusted.

In ST2, the prepared dispersion liquid 5 contained the CNTs 51 having a concentration in the range of 0.0001% to 0.005% and the surfactant 52 having a concentration in the range of 0.05% to 0.08%, as described above.

In ST4, a moving speed in the case where the immersed base material 11 was pulled up was equal to or less than 0.1 μm/s.

In ST4, the operator pulled up the base material 11 along the stacking surface P of the base material 11 in a direction intersecting an opposing direction of the side surfaces of the two electrodes (the first electrode 12a and the second electrode 12b).

In ST4, the CNTs 51 were moved onto the stacking surface P of the base material 11 in a state where the CNTs were oriented in parallel with the interface of the dispersion liquid 5, and were dried.

In addition, the operator measured film thicknesses of the second portion 13e of the manufactured bolometer (A) and the second portion 1300e of the bolometer (B) as average film thicknesses. At this time, the operator directly measured the film thicknesses using a SEM or a TEM, or measured the film thicknesses from observed images captured using any of these microscopes.

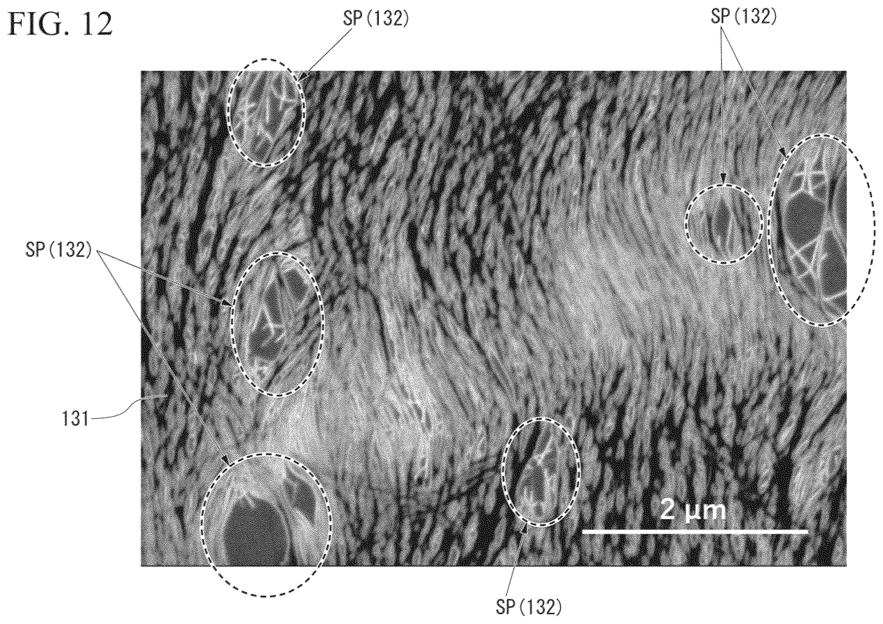

FIG. 12 is a SEM image of the film 13 in the second portion 13e of the bolometer (A).

In FIG. 12, it was confirmed that the film 13 included the base layer 132 (second orientation layer) and the first orientation layer 131. In addition, the first orientation layer was formed with a larger gap than the second orientation layer.

In FIG. 12, it was confirmed that, in the second portion 13e, the base layer 132 (second orientation layer) and the first orientation layer 131 had some parts with a space SP (cavity) where the CNTs 51 were sparsely formed by sporadical adhesion of the CNTs 51.

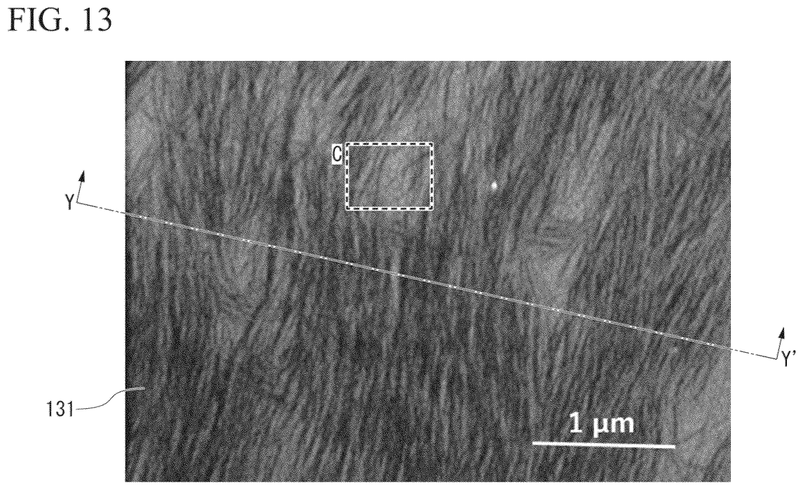

FIG. 13 is a SEM image of the film 1300 in the second portion 1300e of the bolometer (B).

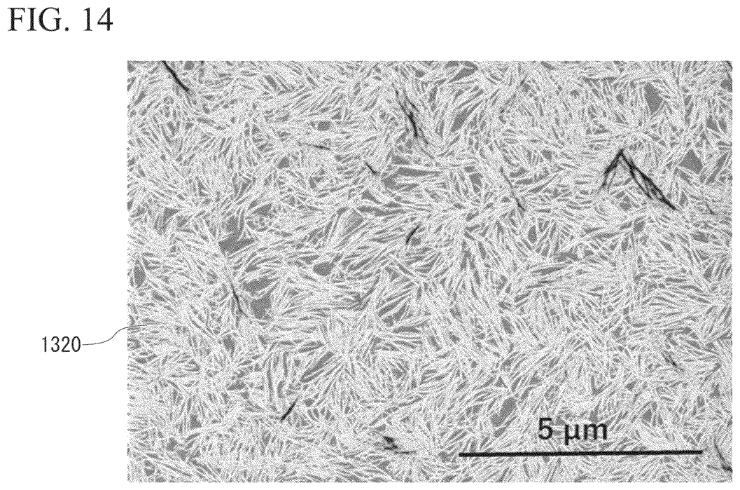

FIG. 14 is an enlarged view of a region C in the SEM image of FIG. 13.

From FIG. 14, it was confirmed that the second portion 1300e included the base layer 1320 between the stacking surface P and the first orientation layer 131, the base layer 1320 being formed such that CNTs were directed to random directions as compared to those of the first orientation layer 131.

From FIG. 13, it was confirmed that the film 1300 of the bolometer (B) included the base layer 1320, which made it difficult to form the space SP (cavity) where the CNTs 51 were sparse, as seen in the bolometer (A).

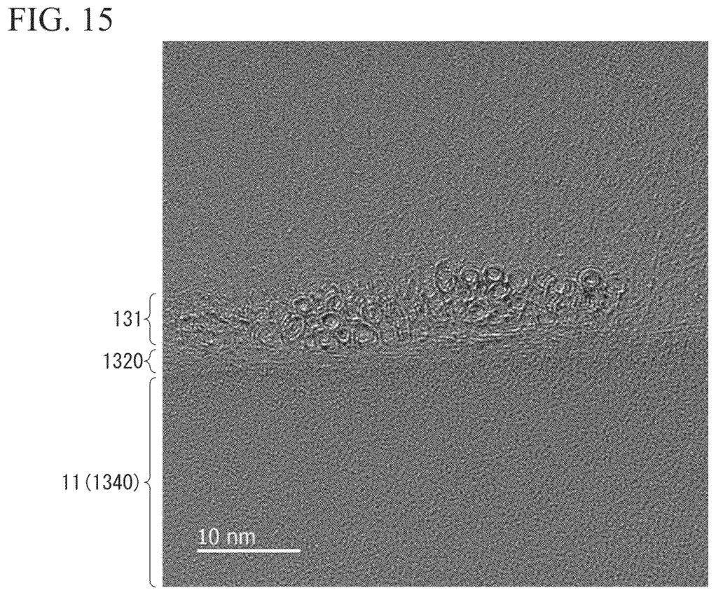

FIG. 15 is a cross-sectional TEM image taken along a cutting line Y-Y′ in the SEM image of FIG. 13.

From FIG. 15, it was confirmed that the film 1300 of the bolometer (B) had the base layer 1320 stacked on the base material 11, and further had the first orientation layer 131 stacked thereon.

From FIG. 15, it was confirmed that, in the base layer 1320, the CNTs 51 were directed to random directions as compared to those of the first orientation layer 131.

From FIG. 15, it was confirmed that the base layer 1320 was constituted by substantially one layer of CNTs 51 and had a film thickness of equal to or less than 2 nm. The first orientation layer 131 was constituted by one to three layers of CNTs 51.

Furthermore, the film thickness of a combination of the base layer 1320 and the first orientation layer 131 was mostly 6.0 nm to 9.0 nm and was a maximum of 10 nm or less. It was confirmed that a maximum average film thickness was 3.4 nm to 9.0 nm and less than 10 nm.

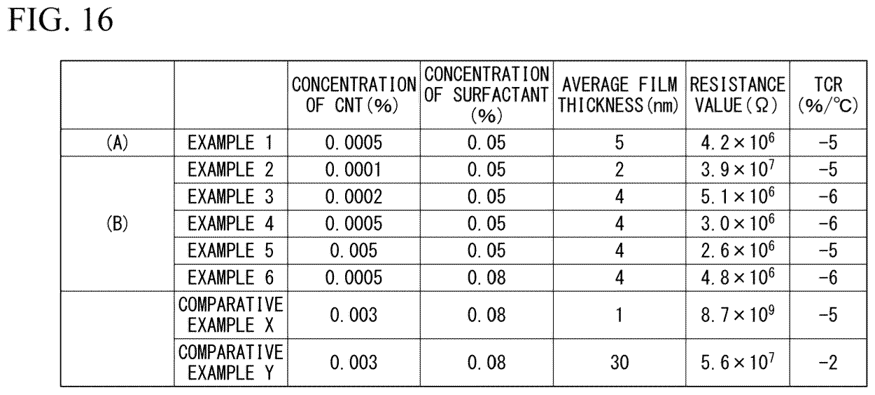

FIG. 16 shows comparison between an average film thickness of each film of a bolometer, and a resistance value and a TCR value at 3V. The concentration of the dispersion liquid 5 used in the case of forming each film is also shown.

In this example, a TCR (%/° C.) is the rate of change in resistance due to a temperature based on a reference temperature of 25° C.

In FIG. 16, Comparative Example X relates to a film manufactured by a casting method, and Comparative Example Y relates to a thick film manufactured by a casting method.

It was confirmed that the film 13 of the bolometer (A) in Example 1 and the film 1300 of the bolometer (B) in Examples 2 to 6 had resistance values smaller than those of the films manufactured by a casting method (Comparative Example 1 and Comparative Example 2).

It was confirmed that the film 13 of the bolometer (A) and the film 1300 of the bolometer (B) had the same absolute value of a TCR as that in Comparative Example X. In the film manufactured by a casting method (Comparative Example X) and the thick film manufactured by a casting method (Comparative Example Y), it was easy to form a conductive path with an increase in the thickness of a film, and thus it was possible to achieve reductions in the resistance of the film 13 and the film 1300. However, it was confirmed that, in the case where the films were manufactured by a casting method, an absolute value of a TCR, which was a temperature coefficient of resistance, decreased with an increase in the thickness of the film. This is because, in the case where a CNT 51, which contains a mixture of semiconducting CNTs and metallic CNTs, is used, the content of the metallic CNTs 51 increases with an increase in the thickness of the film. Although the amount of metallic CNTs contained in the CNT 51 is smaller than the amount of semiconducting CNTs (98 wt %), an increase in the content (number) of metallic CNTs leads to an increase in the number of conductive paths for the metallic CNTs, which has an effect of reducing an absolute value of a TCR.

Although the present disclosure has been described above with reference to the example embodiments, the present disclosure is not limited to the above-described example embodiments. Various modifications that can be understood by a person skilled in the art can be made to the configurations and details of the present disclosure within the scope of the present disclosure. Furthermore, each of the example embodiments can be appropriately combined with other example embodiments.

Some or all of the above-described example embodiments may be described as the following supplementary notes, but are not limited thereto,

### (Supplementary Note 1)

A bolometer including:
a base material that has a stacking surface;
two electrodes each of which has a main surface and a side surface extending from the main surface to the stacking surface; and
a film that contains carbon nanotubes,
wherein the film includes:
a first portion that is stacked on the main surface;
a second portion that is stacked on the stacking surface between the two electrodes; and
a connection portion that connects the first portion and the second portion and is provided on the side surface, and
wherein an average film thickness of the second portion is less than 10 nm.

### (Supplementary Note 2)

The bolometer according to supplementary note 1, in which the second portion includes a first orientation layer, and in which the carbon nanotubes are oriented.

### (Supplementary Note 3)

The bolometer according to supplementary note 2, wherein the second portion further includes a base layer between the stacking surface and the first orientation layer,
wherein the carbon nanotubes in the base layer are directed to random directions as compared to the carbon nanotubes in the first orientation layer.

### (Supplementary Note 4)

The bolometer according to supplementary note 2, wherein
the second portion includes a second orientation layer between the stacking surface and the first orientation layer, the second orientation layer including the carbon nanotubes which are oriented, and
a density of the carbon nanotubes in the second orientation layer is higher than a density of the carbon nanotubes in the first orientation layer.

### (Supplementary Note 5)

A manufacturing method including:
preparing a base material that has a stacking surface, and two electrodes each of which includes a main surface and a side surface extending from the main surface to the stacking surface;
immersing the base material in a dispersion liquid containing carbon nanotubes; and
pulling up the immersed base material at a moving speed of 0.3 μm/s or less such that the stacking surface passes through a liquid surface of the dispersion liquid,
wherein the dispersion liquid contains carbon nanotubes having a concentration of 0.0001% to 0.005%, and a surfactant having a concentration of 0.05% to 0.08%.

### (Supplementary Note 6)

The manufacturing method according to supplementary note 5, wherein the pulling-up includes pulling-up the immersed base material at a moving speed of 0.1 μm/s or less.

### (Supplementary Note 7)

The manufacturing method according to supplementary note 5 or 6, wherein the preparing includes applying a silane coupling agent onto the stacking surface.

### (Supplementary Note 8)

The manufacturing method according to supplementary note 7, wherein the pulling-up includes pulling-up the base material along the stacking surface in a direction intersecting an opposing direction of the side faces of the two electrodes.

### (Supplementary Note 9)

The manufacturing method according to supplementary note 5, wherein the dispersion liquid contains carbon nanotubes at a concentration of 0.0002% to 0.0005%.

### (Supplementary Note 10)

The manufacturing method according to supplementary note 7, wherein the silane coupling agent includes an amino group.

What is claimed is:

1. A bolometer comprising:
a base material that has a stacking surface;
two electrodes each of which has a main surface and a side surface extending from the main surface to the stacking surface; and
a film that contains carbon nanotubes,
wherein the film includes:
a first portion that is stacked on the main surface;
a second portion that is stacked on the stacking surface between the two electrodes; and
a connection portion that connects the first portion and the second portion and is provided on the side surface, and
wherein an average film thickness of the second portion is less than 10 nm.

2. The bolometer according to claim 1, wherein the second portion includes a first orientation layer in which the carbon nanotubes are oriented.

3. The bolometer according to claim 2,
wherein the second portion further includes a base layer between the stacking surface and the first orientation layer, and
wherein the carbon nanotubes in the base layer are directed to random directions as compared to the carbon nanotubes in the first orientation layer.

4. The bolometer according to claim 2,
wherein the second portion includes a second orientation layer between the stacking surface and the first orientation layer, the second orientation layer including the carbon nanotubes which are oriented, and
wherein a density of the carbon nanotubes in the second orientation layer is higher than a density of the carbon nanotubes in the first orientation layer.

5. A manufacturing method comprising:
preparing a base material that has a stacking surface, and two electrodes each of which includes a main surface and a side surface extending from the main surface to the stacking surface;
immersing the base material in a dispersion liquid containing carbon nanotubes; and
pulling up the immersed base material at a moving speed of 0.3 μm/s or less such that the stacking surface passes through a liquid surface of the dispersion liquid,
wherein the dispersion liquid contains carbon nanotubes having a concentration of 0.0001% to 0.005%, and a surfactant having a concentration of 0.05% to 0.08%.

6. The manufacturing method according to claim 5, wherein the pulling-up includes pulling-up the immersed base material at a moving speed of 0.1 μm/s or less.

7. The manufacturing method according to claim 5, wherein the preparing includes applying a silane coupling agent onto the stacking surface.

8. The manufacturing method according to claim 7, wherein the pulling-up includes pulling-up the base material along the stacking surface in a direction intersecting an opposing direction of the side faces of the two electrodes.

9. The manufacturing method according to claim 5, wherein the dispersion liquid contains carbon nanotubes at a concentration of 0.0002% to 0.0005%.

10. The manufacturing method according to claim 7, wherein the silane coupling agent includes an amino group.
